(19) United States
(12) Patent Application Publication
(10) Pub. No.: US 2025/0107113 A1
(43) Pub. Date: Mar. 27, 2025

(54) THREE-DIMENSIONAL RESISTORS

(71) Applicant: International Business Machines Corporation, Armonk, NY (US)

(72) Inventors: Ashim Dutta, Clifton Park, NY (US); Brandon Noland Canedy, Cohoes, NY (US); Chih-Chao Yang, Glenmont, NY (US)

(21) Appl. No.: 18/474,647

(22) Filed: Sep. 26, 2023

(51) Int. Cl. H01C 1/14; H01C 17/06; H01L 23/522

(52) U.S. Cl. CPC H10D 1/474; H01C 1/14; H01C 17/06; H01L 23/5228

(57) ABSTRACT

Aspects of the present invention provide a three-dimensional resistor with at least two horizontal resistive metal elements connected by at least one vertical resistive metal element. Each of the vertical resistive metal elements surrounds a portion of a first dielectric material where the portion of resistive metal surrounding the dielectric material forms a tube of the resistive metal. More than one vertical resistive metal element with a thickness between one and five nanometers can be present between each of two adjacent horizontal resistive metal elements.

### BACKGROUND

The present invention relates generally to the field of semiconductor device technology and more particularly to a method of forming a three-dimensional resistor structure for semiconductor chip applications and the resulting structure.

The amount of data we process is rapidly increasing at a rate higher than that of Moore's law. Increasing system performance requirements, driven at least in part by the increasing use of artificial intelligence, continue to drive tighter pitches in semiconductor devices and smaller semiconductor chips. For logic scaling at the two-nanometer node, planar and non-planar semiconductor device structures, such as metal-oxide-semiconductor field-effect transistors (MOSFETs), must be scaled to smaller dimensions. With the evolution of reduced-size transistors, semiconductor technology has progressed from planar transistor designs to three-dimensional type logic device designs such as finFET designs which are further evolving into gate-all-around transistor designs. The progression to three-dimensional semiconductor devices helps achieve a reduced device footprint.

### SUMMARY

Embodiments of the present invention provide a semiconductor structure for a three-dimensional resistor. The three-dimensional resistor includes at least two horizontal resistive metal elements connected by at least one vertical resistive metal element. Each of the vertical resistive metal elements surrounds a portion of a first dielectric material where the portion of resistive metal surrounding the dielectric material forms a tube of the resistive metal.

Embodiments of the present invention provide a three-dimensional resistor which includes more than two horizontal resistive metal elements, where one of two adjacent horizontal resistive metal elements includes a vertical tube of the resistive metal surrounding a portion of a dielectric material. The vertical tube of the resistive metal connects the two adjacent horizontal resistive metal elements. The three-dimensional resistor includes at least two vertical tubes surrounding the portion of the dielectric material. The vertical tubes of the resistive metal are vertically aligned and stacked. The vertically aligned and stacked vertical tubes of the resistive metal connect two adjacent horizontal resistive metal elements of the more than two horizontal resistive metal elements.

### BRIEF DESCRIPTION OF THE DRAWINGS

The aspects, features, and advantages of various embodiments of the present invention will be more apparent from the following description taken in conjunction with the accompanying drawings.

FIG. 1 is a cross-sectional view of a semiconductor structure after forming a bottom electrode in a first dielectric material in accordance with an embodiment of the present invention.

FIG. 2 is a cross-sectional view of the semiconductor structure after depositing and patterning a layer of a resistive metal in accordance with an embodiment of the present invention.

FIG. 3 is a cross-sectional view of the semiconductor structure after depositing and patterning another dielectric material on the resistive metal in accordance with an embodiment of the present invention.

FIG. 4 is an illustration of one example of a top view of the semiconductor structure of FIG. 3 in accordance with an embodiment of the present invention.

FIG. 5 is a cross-sectional view of the semiconductor structure after forming vertical side elements of the resistor metal in accordance with an embodiment of the present invention.

FIG. 6 is a cross-sectional view of the semiconductor structure after depositing another layer of resistive metal on the vertical side elements in accordance with an embodiment of the present invention.

FIG. 7 is a cross-sectional view of the semiconductor structure after forming a second vertical element and depositing another resistive metal layer with a top electrode on the new resistive metal layer in accordance with an embodiment of the present invention.

FIG. 8 is a cross-sectional view of a semiconductor structure after depositing and patterning a dielectric material on a first dielectric material with an embedded bottom electrode in accordance with an embodiment of the present invention.

FIG. 9 is a cross-sectional view of the semiconductor structure of an example of depositing and patterning a thicker layer of the dielectric layer on the first dielectric material in accordance with an embodiment of the present invention.

FIG. 10 is a cross-sectional view of the semiconductor structure after depositing and patterning a layer of highly resistive metal on the patterned dielectric in accordance with an embodiment of the present invention.

FIG. 11 is a cross-sectional view of the semiconductor structure after depositing and planarizing another layer of dielectric material in accordance with an embodiment of the present invention.

FIG. 12 is a cross-sectional view of the semiconductor structure after depositing and patterning another dielectric material and another layer of highly resistive metal in accordance with an embodiment of the present invention.

FIG. 13 is a cross-sectional view of the semiconductor structure after depositing and planarizing a dielectric material and forming a top electrode in accordance with an embodiment of the present invention.

FIG. 14 is a cross-sectional view of a semiconductor structure with two stacked three-dimensional resistors formed with the highly resistive metal in accordance with an embodiment of the present invention.

### DETAILED DESCRIPTION

Embodiments of the present invention recognize increasing system performance requirements, driven at least in part by the increasing use of artificial intelligence, which continues to drive tighter pitches in semiconductor devices and smaller semiconductor chips. With the evolution of reduced-size transistors, semiconductor technology has progressed from planar transistor designs to three-dimensional type logic device designs such as finFET designs which are further evolving into gate-all-around transistor designs.

Embodiments of the present invention recognize that resistors are one of the most common electrical components and are used in almost every electrical device. Embodiments of the present invention recognize that resistors are typically formed as two-dimensional elements. Embodiments of the present invention recognize that providing space-efficient, three-dimensional high-resistance resistors would be desirable.

Embodiments of the present invention provide a number of three-dimensional resistor structures and methods for forming the three-dimensional resistors. Embodiments of the present invention disclose the three-dimensional resistor that improves scaling feasibility compared to conventional two-dimensional resistors. The disclosed three-dimensional resistors provide an opportunity for a smaller resistor footprint with a higher electrical resistance due at least in part to the very thin vertical elements (e.g., 1 nm) of the three-dimensional resistors. Additionally, embodiments of the present invention provide a semiconductor designer or a system designer with design flexibility using the three-dimensional resistors disclosed in embodiments of the present invention. Embodiments of the present invention provide any number of resistive metal layers and dielectric materials that can be mixed and matched as needed for a desired electrical performance or manufacturing process ease. Additionally, embodiments of the present invention provide the ability to stack any number of horizontal resistive metal layers with any number of vertical elements to form three-dimensional resistors.

Embodiments of the present invention provide two or more horizontal layers of resistive metal(s), where each of the horizontal resistive metal layers can be composed of one or more layers of resistive metals. One of the at least two horizontal resistive metal layers connects to a metal level such as a bottom electrode or metal level below the bottom electrode, and another of the horizontal resistive metal layers connects to another metal level such as a top electrode of a metal level above and connected to the three-dimensional resistor. The two or more horizontal layers of the resistive metal can be composed of the same resistive metal or different resistive metals. In addition to the two or more horizontal metal layers, embodiments of the present invention include at least one vertical resistive metal element contacting each horizontal resistive metal layer to a second adjacent horizontal resistive metal layer. The three-dimensional resistor is formed by at least one vertical resistive metal element contacting each of the horizontal resistive metal layers above and below the vertical element. Embodiments of the present invention provide more than two horizontal resistive metal layers, where each adjacent horizontal resistive metal layer connects to the adjacent horizontal resistive metal layers by a vertical resistive element.

In embodiments, the vertical resistive metal element is around and contacting the sidewall of a patterned and shaped portion of a dielectric material. The dielectric material can be patterned to form a circular, oval, rectangular, or another shaped column. The vertical resistive metal element forms a tube around the dielectric material. The tube of the vertical resistive metal connecting two horizontal resistive metal layers can have a variety of shapes including round, oval, and rectangular, and may reside completely on a portion of a horizontal resistive metal layer or may be larger than the horizontal resistive metal layer so that only portions of the tube contact the horizontal resistive metal layer.

Embodiments of the present invention disclose that the at least one vertical resistive element or tube is a thin resistive element providing a high electrical resistance of the three-dimensional resistor. In embodiments of the present invention, the vertical resistive metal elements are a vertical portion of a layer of the resistive metal that also forms the horizontal resistive metal elements. In other embodiments, the vertical resistive metal elements are a vertical tube connecting two horizontal resistive metal layers, where the vertical resistive metal and the horizontal resistive metal elements are composed of different resistive metal materials.

Embodiments of the present invention disclose that the thin vertical tubes of the vertical resistive element can be offset or staggered on different horizontal resistive metal layer or directly stacked above each other. The disclosed embodiments of the three-dimensional resistors provide design flexibility, a higher electrical resistance, and an opportunity for a smaller resistor footprint compared to a two-dimensional resistor with a similar resistance.

Detailed embodiments of the claimed structures and methods are disclosed herein. The method described below does not form a complete process flow for manufacturing integrated circuits, such as semiconductor devices. The present embodiments can be practiced in conjunction with the integrated circuit fabrication techniques currently used in the art, for semiconductor devices, and only so much of the commonly practiced process steps are included as are necessary for an understanding of the described embodiments. The figures are not drawn to scale, but instead are drawn to illustrate the features of the described embodiments. Specific structural and functional details disclosed herein are not to be interpreted as limiting, but merely as a representative basis for teaching one skilled in the art to variously employ the methods and structures of the present disclosure. In the description, details of well-known features and techniques may be omitted to avoid unnecessarily obscuring the presented embodiments.

References in the specification to “one embodiment”, “other embodiment”, “another embodiment”, “an embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. The terms “overlying”, “atop”, “over”, “on”, “positioned on” or “positioned atop” mean that a first element is present on a second element wherein intervening elements, such as an interface structure, may be present between the first element and the second element. The term “direct contact” means that a first element and a second element are connected without any intermediary conducting, insulating or semiconductor layers at the interface of the two elements.

In the interest of not obscuring the presentation of the embodiments of the present invention, in the following detailed description, some of the processing steps, materials, or operations that are known in the art may have been combined together for presentation and for illustration purposes and in some instances may not have been described in detail. Additionally, for brevity and maintaining a focus on distinctive features of elements of the present invention, description of previously discussed materials, processes, and structures may not be repeated with regard to subsequent Figures. In other instances, some processing steps or operations that are known may not be described. It should be understood that the following description is rather focused on the distinctive features or elements of the various embodiments of the present invention.

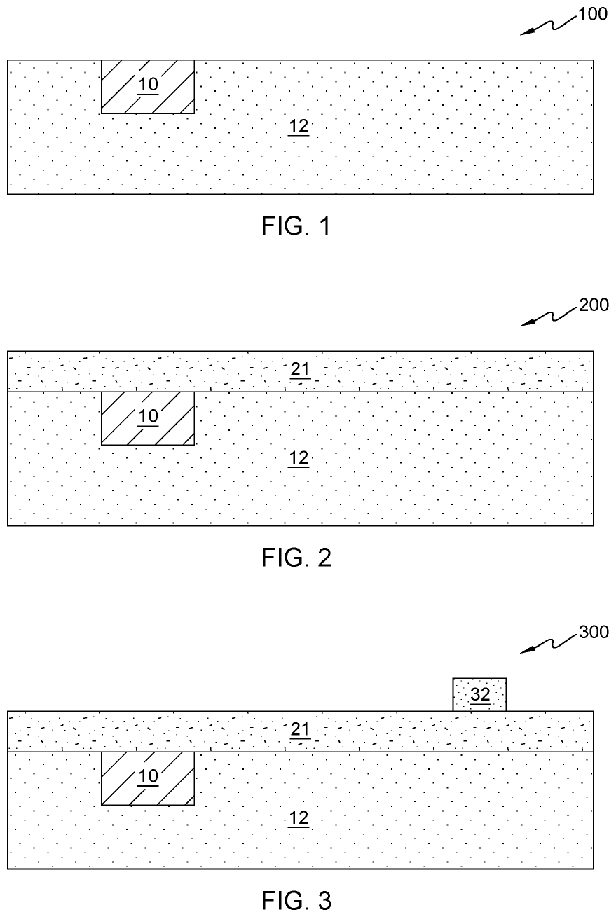

FIG. 1 is a cross-sectional view of semiconductor structure 100 after forming bottom electrode 10 in dielectric material 12 in accordance with an embodiment of the present invention. Dielectric material 12 can be any dielectric material used in semiconductor chips. For example, dielectric material 12 can be SiO₂, SiN, SiO, SiC, SiN (H), SiCN, or any low-k dielectric material SiCOH or SiCNO but is not limited to these dielectric materials.

In various embodiments, the metal element, labeled 10, is one of a metal line, a metal contact, or a bottom electrode. In various embodiments, bottom electrode 10 may be formed in any front-end-of-line (FEOL), middle-of-line (MOL), or back-end-of-line metal (BEOL) layer or metal level. Hereinafter, the metal element, labeled 10, will be identified as bottom electrode 10. Bottom electrode 10 can be composed of one or more metal materials such as but not limited to tungsten (W), copper (Cu), aluminum (Al), cobalt (Co), ruthenium (Ru), iridium (Ir), tungsten nitride (WN), tungsten carbide (WC), gold (Au), aluminum (Al) or multilayered stacks thereof. The conductive metallic material of bottom electrode 10 may be formed by a deposition process such as, for example, chemical vapor deposition (CVD), physical vapor deposition (PVD), plasma enhanced CVD (PECVD), sputtering, atomic layer deposition (ALD) or plating. A planarization process or an etch back process may follow the deposition of the conductive metallic material.

FIG. 2 is a cross-sectional view of semiconductor structure 200 after depositing and patterning a layer of resistive metal 21 in accordance with an embodiment of the present invention. As depicted, FIG. 2 includes the elements of FIG. 1 and resistive metal 21. Resistive metal 21 may be deposited by any suitable metal deposition process such as but not limited to chemical vapor deposition (CVD), physical vapor deposition (PVD, electroplating, or atomic layer deposition (ALD). A typical thickness of resistive metal 21 in a MOL metal layer can be in the range of 5 to 50 nanometers (nm) however, the thickness of resistive metal 21 is not limited to this range. In various embodiments, resistive metal 21 is composed of one or more resistive metals or resistive materials such as tantalum nitride (TaN), titanium nitride (TIN), WN, and other resistive metal nitrides or oxides.

Resistive metal 21 may be patterned and etched using known lithographic and wet or dry etching processes. In various embodiments, resistive metal 21, after patterning and etching, forms one or more lines. In other embodiments, resistive metal 21, after patterning and etching, forms a rectangular pad, a round pad, a portion of a line, or an oval pad, where the size of the pad or line formed after etching can be determined by the electrical performance of the resistor, the available space, and the electrical requirements of the completed semiconductor chip (e.g., the remaining resistive metal 21 can be larger or smaller depending on the semiconductor chip electrical performance and the available space).

FIG. 3 is a cross-sectional view of semiconductor structure 300 after depositing and patterning dielectric material 32 on resistive metal 21 in accordance with an embodiment of the present invention. As depicted, FIG. 3 includes the elements of FIG. 2 with a portion of dielectric material 32.

Dielectric material 32 may be the same dielectric material as dielectric material 12 or a different dielectric material. Dielectric material 32 can be deposited by any known dielectric material deposition process (e.g., CVD, PVD, ALD). Using known lithography process for patterning dielectric material 32 and known etching processes such as one or more wet or dry etching processes (e.g., reactive ion etch (RIE)), portions of dielectric material 32 can be removed. A pillar or a column of dielectric material 32 remains on resistive material 21. The remaining pillar or column of dielectric material 32 may have any shape (e.g., a circle, an oval, a rectangle, a square with fins, a star). In one embodiment, the remaining portion of dielectric material 32 is wider than the remaining portion of resistive material 21. In another embodiment, the remaining portion of dielectric material 32 is smaller than the width of the remaining portion of resistive material 21.

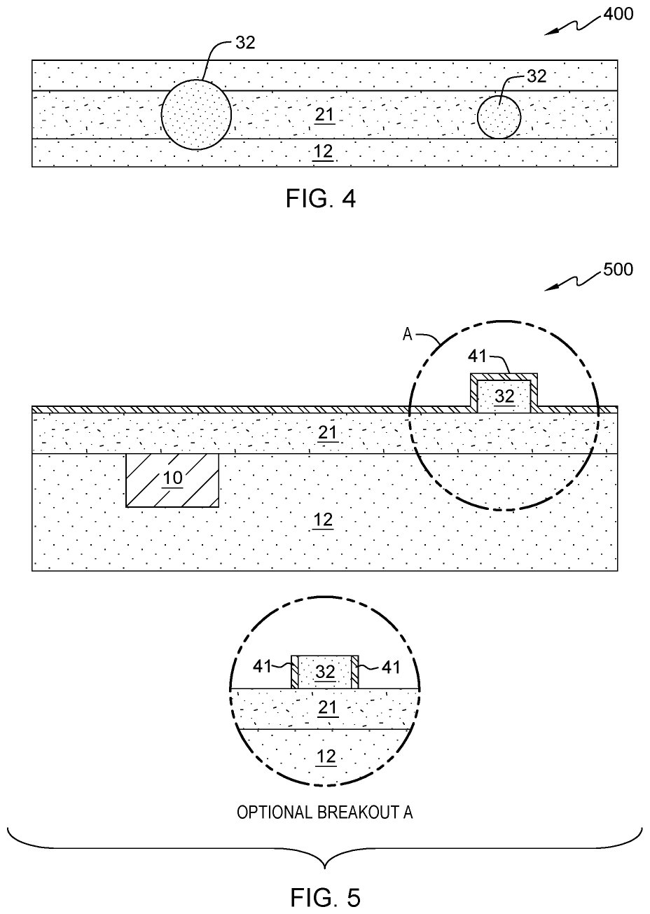

FIG. 4 is an illustration of one example of a top view 400 of semiconductor structure 300 of FIG. 3 in accordance with an embodiment of the present invention. As depicted, FIG. 4 includes the exposed top surfaces of dielectric material 12, dielectric material 32, and resistive material 21. FIG. 4 depicts one example of two top views of the top surface of semiconductor structure 300. As previously discussed, the shape of dielectric material 32 in other examples can be a rectangle, an oval, a star, a square with fins, etc. As depicted in the leftmost circular portion of dielectric material 32, in an embodiment, the remaining portion of dielectric material 32 after etching is wider than resistive material 21. In this embodiment, two facing portions of dielectric material 32 remain on resistive metal 21. As depicted in the rightmost portion of dielectric material 32, the remaining portion of dielectric material 32 has a diameter or width that is the same width as the width of resistive metal 21. In some embodiments, the width or diameter of dielectric material 32 is less than the width or diameter of resistive material 21.

FIG. 5 is a cross-sectional view of the semiconductor structure after forming vertical side elements of resistor metal in accordance with an embodiment of the present invention. As depicted, FIG. 5 includes the elements of FIG. 4 with a patterned layer of resistive metal 41 on resistive metal 21 and dielectric material 32. Optional breakout A is also illustrated in FIG. 5. Optional breakout A illustrates another embodiment for forming the vertical sides of resistive metal 41.

Resistive metal 41 is a highly resistive metal such as TaN, TiN, WN, a metal nitride, or a metal oxide but is not limited to these resistive materials. In some embodiments, resistive metal 41 can be a different resistive metal material than resistive metal material 21. In other embodiments, resistive metal 41 is the same resistive metal material as resistive metal 21.

In various embodiments, resistive metal 41 is deposited by ALD. The deposition of resistive metal 41 may occur by other processes capable of depositing a layer of resistive metal 41 (e.g., CVD, PECVD, PVD). A typical thickness of the deposited resistive metal 41 can be in the range of 1 nm to 5 nm thick metal layer but is not limited to these thicknesses. For example, resistive metal 41 can have a thickness of 1 nm layer. The thin layer of resistive metal 41 increases the resistance of any of the completed three-dimensional resistor structures (e.g., depicted in FIGS. 7, 13, and 14).

As depicted in FIG. 5, in various embodiments, after depositing resistive metal 41, the metal layer is patterned and etched using known semiconductor manufacturing processes (e.g., using lithography and a wet or dry etching process). In these examples, resistive metal 41 forms an upside-down cup-like cap on and around dielectric material 32. In some embodiments, the width or shape of resistive metal 41 after etching is the same as the width or shape of resistive metal 21. In other words, if resistive metal 21 forms a line, then, after etching, resistive metal 41 forms a line on resistive metal 21 with an upside-down cup-like portion where the top surface of the upside-down cup or portion of resistive metal 41 resides on dielectric material 32 with vertical sidewalls contacting dielectric material 32 and resistive metal 21.

In some examples, as previously discussed with respect to FIG. 4, dielectric material 32 can be wider than the width of the line or remaining resistive material 21. In these embodiments, only a portion of resistive metal 41 around dielectric material 32 contacts resistive material 21. For example, when a round pillar of dielectric material 32 has a diameter greater than the width of resistive material 21 only two portions of the tube or sidewall of resistive material 41 surrounding dielectric material 32 contact resistive material 21.

In another embodiment, as depicted in Optional Breakout A, instead of patterning and etching resistive metal 41, an anisotropic etch can be used to remove resistive metal 41 on the horizontal surfaces of resistive metal 21 and dielectric material 32. For example, after performing a reactive ion etch (RIE), only the vertical elements or sidewall of resistive metal 41 remain on the vertical surfaces of dielectric material 32. In these embodiments, only a vertical tube of resistive metal 41 remains contacting resistive metal 21 after RIE.

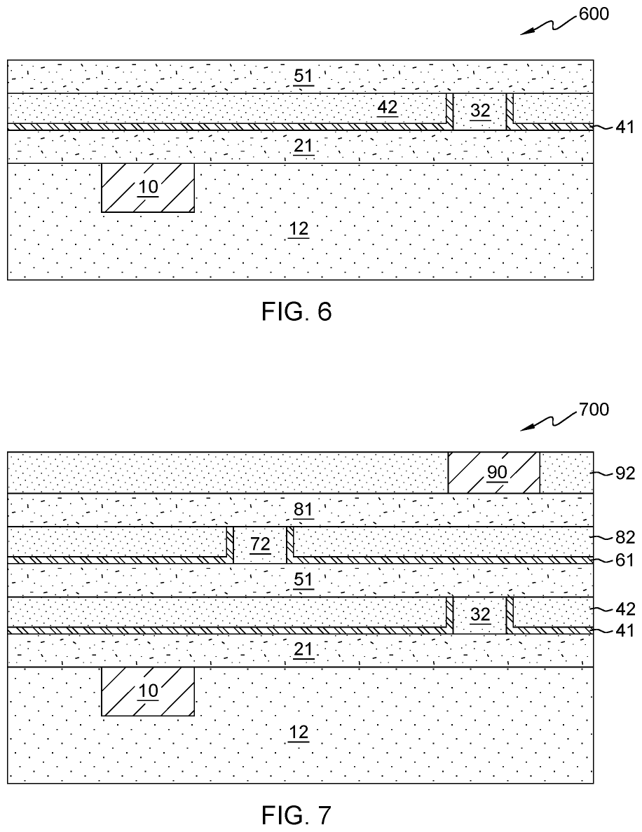

FIG. 6 is a cross-sectional view of semiconductor structure 600 after depositing dielectric material 42, performing a chemical-mechanical polish (CMP), depositing resistive metal 51, and patterning resistive metal 51 in accordance with an embodiment of the present invention. As depicted, FIG. 6 includes the elements of FIG. 5 with dielectric material 42 and resistive metal 51. In semiconductor structure 600, the horizontal portions of resistive metal 21 and resistive metal 41 can be a first horizontal resistive element of a three-dimensional resistor, resistive metal 51 can be a second horizontal resistive element, and the vertical sidewall of resistive metal 41 can be a horizontal resistive element of the three-dimensional resistor.

Dielectric material 42 can be the same dielectric material as one or both of dielectric material 12 and dielectric material 32. In other examples, dielectric material 42 can be a different dielectric material than one or both of dielectric material 12 and 32.

Dielectric material 42 can be deposited over resistive material 32 using known dielectric material deposition processes. Dielectric material 42 extends above the top surface of dielectric material 32. In various embodiments, the top surface of dielectric material 42 is planarized (e.g., by CMP) such that the top surface of resistive material 41 is removed. For example, a tube of resistive material 41 contacts resistive metal 21 and extends up to contact resistive material 51. The tube of resistive metal 41 surrounds the sidewall of dielectric material 32 and connects with the horizontal portion of resistive metal 41 on resistive metal 21. As previously discussed, the tube may be a round tube, a square tube, or any other shaped tube. The remaining vertical sides or sidewall of resistive metal 41 forming the tube can create a three-dimensional resistor with the horizontal lines or portions of resistive metal 21, resistive metal 41, and resistive metal 51.

In some examples, the tube of resistive metal 41 connects to the horizontal portions of resistive metal 41 and can have a tube width or diameter that is greater than the width of resistive metal 51 and resistive metal 41. As previously discussed with respect to FIG. 5, when the width of the tube of resistive metal 41 is greater than the width of resistive metal 21 and resistive metal 51 lines, then only two small, curved portions of the tube of resistive metal 41 contact both resistive metal 21 and resistive metal 51. Using only the two small, curved portions of the tube of resistive metal 41 to provide electrical contact between resistive metal 21 and resistive metal 51 may further increase the resistance of the three-dimensional resistor composed of resistive metal 41, resistive metal 21, and resistive metal 51, where a vertical portion of resistive metal 41 is around dielectric material 32.

In another embodiment, the planarization of dielectric material 42 stops at the top surface of resistive material 41 (i.e., resistive material remains on top of and around the sidewalls of dielectric material 32). In this example, resistive metal 41 on and extends upward from resistive metal 21 forming an upside-down cup-like structure or a tube of resistive metal 41 with one closed end. In this case, the sidewall of resistive metal 41 and the top surface of resistive metal 41 on dielectric material 32 contacts resistive metal 51.

In yet another embodiment, resistive metal 41 is only a vertical tube of resistive material without the horizontal portions of resistive metal 41. As discussed with respect to FIG. 5 and depicted in Optional Breakout A, a directional etching process (e.g., RIE) can be used to remove the horizontal portions of resistive metal 41. In this embodiment, only the remaining vertical sides or sidewall of resistive metal 41 form a vertical tube that will be used to form the three-dimensional resistor.

Resistive metal 51 can be the same resistive metal as resistive metal 21 and resistive metal 41. In some cases, resistive metal 51 is a different resistive metal as one or both of resistive metal 21 and resistive metal 41. Resistive metal 51 can be deposited using the deposition processes discussed with respect to the deposition of resistive metal 21. In some embodiments, the thickness of resistive metal 51 is greater than the thickness of resistive metal 41. In some cases, the thickness of resistive metal 51 and resistive metal 41 is the same.

Using known lithography and etching processes, resistive metal 51 can be etched. In some cases, the etching of resistive metal 51 forms a line or another shape of the resistive metal. For example, after etching, resistive metal 51 may have a similar or the same shape and/or size as resistive metal 41. In one example, resistive metal 51 has a different shape than resistive metal 41.

FIG. 7 is a cross-sectional view of semiconductor structure 700 after patterning dielectric material 72, depositing and patterning resistive metal 61 on resistive metal 51, depositing and planarizing dielectric material 82, depositing and patterning resistive metal 81, and forming top electrode 90 in accordance with an embodiment of the present invention.

As depicted, FIG. 7 includes dielectric material 12, bottom electrode 10, resistive metal 21, dielectric material 32, dielectric material 42, resistive metal 51, resistive metal 61, dielectric material 72, dielectric material 82 on and resistive metal 61, dielectric material 92 on resistive metal 81 and surrounding top electrode 90. As previously discussed regarding bottom electrode 10, and as known to one skilled in the art, top electrode 90 can be one of a metal line, a top electrode, a portion of a metal feature (e.g., power line or plane) or a contact in any metal layer (e.g., a metal layer or level in the FEOL, MOL, or BEOL).

Dielectric material 72, dielectric material 82, and dielectric material 92 can be the same dielectric material as one or more of dielectric materials 12, 32, 42, 72, 82, or 92. In other cases, each of dielectric material 72, 82 and dielectric material 92 can be different dielectric materials than one or more of dielectric materials 12, 32, 42, 72, 82, or 92.

In some embodiments, resistive metal 61 and resistive metal 81 can be the same resistive metal as one or more of resistive metal 41, resistive metal 21, and resistive metal 51. For example, resistive metal 41 and 81 can be the same resistive metal while resistive metal 21, 51, and 81 can be the same resistive metal. In another example, resistive metal 41 and 51 are the same resistive metal. In another example, resistive metals 21, 41, 51, 61, and 81 are the same resistive metals. In other embodiments, resistive metal 61 and resistive metal 81 are different resistive metals. For example, resistive metal 61 is TaN and resistive metal 81 is TiN. In some cases, some or all of resistive metal 21, 41, 51, 61, and 81 are different resistive metals. For example, each of resistive metal 21, 41, 51, 61, and 81 are different resistive metals (e.g., TaN for resistive metal 21, TiN for resistive metal 41, WN for resistive metal 51, another metal nitride for resistive metal 61, and a metal oxide for resistive metal 81). Each of resistive metal 21, 41, 51, 61, and 81 can be composed of one or more resistive metals such as tantalum nitride (TaN), titanium nitride (TiN), WN, or other metal nitrides or oxides but are not limited to these resistive metals.

Dielectric materials 72, 82, and 92 along with resistive metal 61 and 81 can be formed as depicted in FIG. 7 using the processes and materials previously discussed with reference to FIGS. 1-6. Each of dielectric material 12, 32, 42, 72, 82, and 92 can be different or the same as one or more of dielectric material 12, 32, 42, 72, 82, and 92.

In semiconductor structure 700, (1) the horizontal portions of resistive metal 21 and resistive metal 41 can be a first horizontal resistive element of a three-dimensional resistor, (2) the horizontal portion of resistive metal 61 resistive metal 51 can be a second horizontal resistive element of the three-dimensional resistor, (3) resistive metal 81 can be a third horizontal resistive element, (4) the vertical sidewall of resistive metal 41 can be a first vertical resistive element of the three-dimensional resistor, and (5) the vertical sidewall of resistive metal 61 can be a second vertical resistive element of the three-dimensional resistor.

Semiconductor structure 700 depicts one example of a three-dimensional resistor where the thin vertical sidewalls (e.g., less than 5 nm thick) of resistive metal 41 and resistive metal 61 create a high electrical resistance in the three-dimensional resistor depicted in FIG. 7. The three-dimensional resistor in semiconductor structure 700 includes the horizontal portions or layers of resistive metal 21, resistive metal 41, resistive metal 51, resistive metal 61, resistive metal 81 and the vertical portions of resistive metal 41 and resistive metal 62. FIG. 7 depicts two horizontal layers that are composed of two layers resistive metals and one single layer of resistive metal 81 where each adjacent horizontal layer of the resistive metal material is connected by a vertical portion of a resistive metal layer. As depicted in FIG. 7, the first horizontal layer with two layers of resistive metal is composed of resistive metal 21 and resistive metal 41. The second horizontal layer with two layers of resistive metal is composed of resistive metal 51 and resistive metal 61. In an embodiment, the horizontal layers of resistive metal can each be a single layer of resistive metal as depicted later in FIG. 13. As known to one skilled in the art, using the processes and materials discussed to form semiconductor structure 700, in other embodiments, any number of horizontal layers of resistive metals connected by vertical tubes or portions of vertical tubes of the resistive metals can be formed.

For example, using the processes discussed with respect to Optional Breakout A of FIG. 5, two single layers (e.g., resistive metal 41 and 51) can be connected by a vertical tube of resistive metal 41 (i.e., without a horizontal portion of resistive metal 41). As known to one skilled in the art, any number of combinations of vertical and horizontal portions of any number of layers of resistive metals and dielectric materials can be created with the processes discussed with respect to FIGS. 1-7.

Creating the three-dimensional resistor depicted in semiconductor structure 700 can provide a high-resistance resistor with a small footprint where the resistance of the three-dimensional resistor of semiconductor structure 700 is, in a large part determined, by the thickness of the vertical tubes of resistive metal. The resistance of the three-dimensional resistor can vary depending on the electrical resistance of the resistive metals selected for each layer and the layer thickness, the height and thickness of the vertical portions or tubes of the resistive metal (e.g., the tube thicknesses is in the range of 1 to 5 nm), the number of layers of resistive metals, and the number and position of the vertical elements or tubes of the resistive metal, for example. Providing a high-resistance three-dimension resistor using the methods and materials discussed in embodiments of the present invention can reduce the footprint of the resistor compared to two-dimension resistors providing a similar resistance. Providing a three-dimensional resistor with a smaller footprint than a two-dimensional resistor with the same electrical resistance can provide more semiconductor real estate or space for semiconductor device interconnect wiring. Additionally, embodiments of the present invention provide both material and design flexibility (e.g., number of resistive metal layers and resistive metals) for the semiconductor chip or system designer.

As previously discussed, in other examples, bottom electrode 10 and top electrode 90 can be lines or contacts in any metal level of a semiconductor chip. For example, bottom electrode 10 can be a line in one of a BEOL, MOL, or the FEOL metal layer.

Semiconductor structure 700 depicts an example of a multi-layer three-dimensional resistor. While semiconductor structure 700 depicts a three-dimensional resistor composed of resistive metal 21, resistive metal 41 that includes the vertical tube of resistive metal 41 connecting to resistive metal 51, resistive metal 61 with the vertical tube connecting to resistive metal 81, in other examples, two horizontal resistive metal layers and one vertical resistive metal tube may form the three-dimensional resistor. In other embodiments, more than three layers of the resistive metal with adjacent resistive metal layers connected by one or more thin, vertical tubes of the resistive metal create the multi-layer three-dimensional resistor.

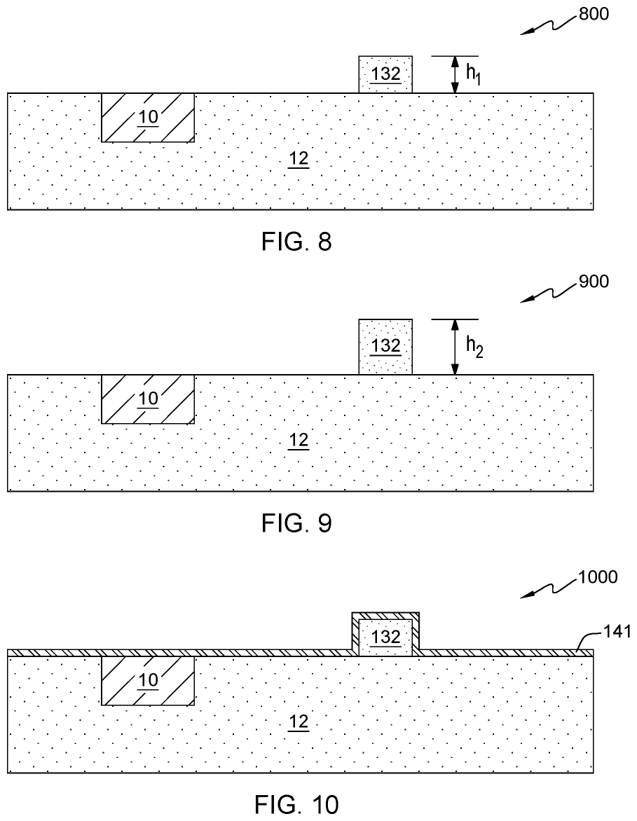

FIG. 8 is a cross-sectional view of semiconductor structure 800 after depositing and patterning dielectric material 132 on dielectric material 12 with bottom electrode 10 in accordance with an embodiment of the present invention. As depicted, FIG. 1 includes dielectric material 12, bottom electrode 10, and dielectric material 132.

As discussed with reference to FIG. 1, dielectric material 12, bottom electrode 10, and dielectric material 132 can be any suitable dielectric material used in semiconductor devices or metal material for forming lines and electrodes (e.g., Cu, W, Ru). Top electrode 10 can be a line or contact in any metal level (e.g., BEOL, MOL, or FEOL metal layer). Also, illustrated in FIG. 8 is a height, h1 of dielectric material 132 after deposition and etching.

FIG. 9 is a cross-sectional view of semiconductor structure 900 with a thicker layer of dielectric material 132 after depositing and patterning the thicker layer of dielectric material 132 on dielectric material 12 in accordance with an embodiment of the present invention. As depicted, FIG. 2 includes the elements of FIG. 1 but with a thicker layer of dielectric material 132. As illustrated in FIG. 9, the height, h2, of dielectric material 132 after patterning is greater than the height, h1, depicted in FIG. 8.

Depositing and patterning a thicker layer of dielectric material can form a higher sidewall of the resistive material deposited after depositing another layer of resistive metal over dielectric material 132 in later processes. A higher sidewall of the resistive material can provide a slightly higher resistance of the three-dimensional resistor after the completion of the semiconductor structure. For example, if the thicker layer of dielectric material 132 depicted in FIG. 9 was used in semiconductor structure 1300, the resulting electrical resistance of the three-dimensional resistor of semiconductor structure 1300 would be slightly higher than the electrical resistance of the three-dimensional resistor formed using dielectric material 132 depicted in FIG. 8 with a height, h1.

FIG. 10 is a cross-sectional view of semiconductor structure 1000 after depositing and patterning a layer of resistive metal 141 on dielectric material 132 in accordance with an embodiment of the present invention. As depicted, FIG. 10 includes the elements of FIG. 1 and resistive metal 141. Resistive metal 141 can be deposited by ALD as previously discussed with reference to FIG. 4. In various embodiments, resistive metal 141 is a thin layer of resistive metal (e.g., in the range of 1 nm to 5 nm thick but is not limited to these thicknesses). Resistive metal 141 can be any of the resistive metals discussed with reference to FIGS. 1-7.

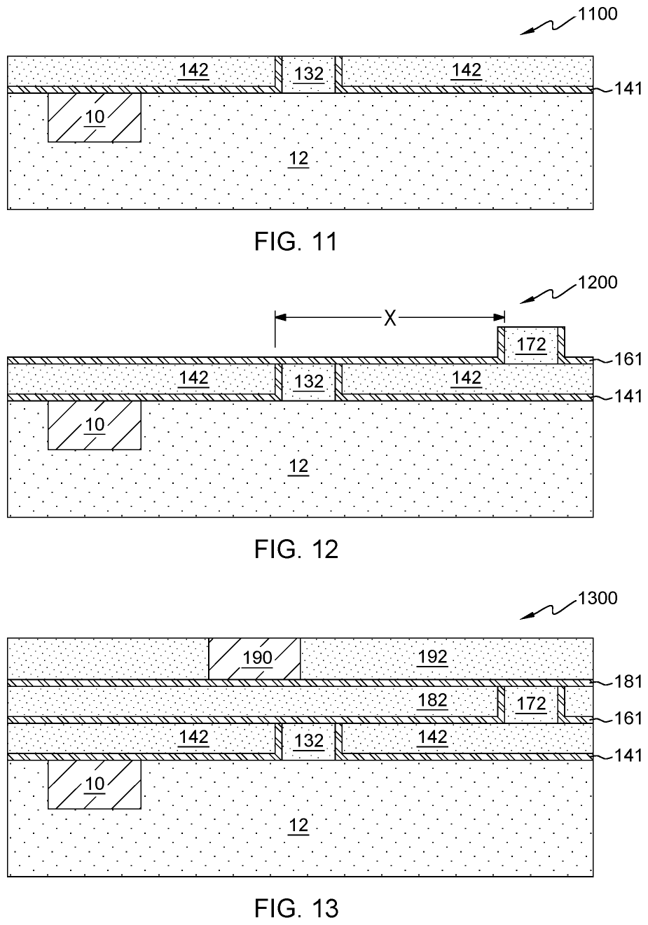

FIG. 11 is a cross-sectional view of semiconductor structure 1100 after depositing and planarizing dielectric material 142 in accordance with an embodiment of the present invention. As depicted, FIG. 11 includes the elements of FIG. 10 without the top surface of resistive metal 141 on dielectric material 132 and with dielectric material 142.

Using known dielectric material deposition processes, dielectric material 142 can be deposited on resistive metal 141. Dielectric material 142 can be any suitable dielectric material for semiconductor chip manufacture. For example, dielectric material 142 can be the same dielectric material as dielectric material 132. Dielectric material 142 can be the same dielectric material as one or more of dielectric material 12, 32, 132, 72, 82, or 92, for example, or dielectric material 142 can be a different dielectric material.

After planarizing the top surface of semiconductor structure 1100, for example, by CMP, the top portion of resistive metal 141 and dielectric material 142. In some cases, a top portion of dielectric material 132 may also be removed. The sidewall of resistive metal 141 remain on dielectric material 132.

In one embodiment, another layer of resistive metal 141 is deposited directly on dielectric material 142, dielectric material 132, and the exposed sidewall of the tube of resistive metal 141 to create a three-dimensional resistor. In this embodiment, the three-dimensional resistor is composed of the horizontal portions of the two layers of resistive metal 141 (i.e., over and under dielectric material 142) and the vertical sidewall or vertical tube of resistive metal 141 surrounding dielectric material 132. Another metal layer or metal level can be formed on the second layer of resistive metal 141 (not depicted in FIG. 11) to form a top electrode or a line (not depicted in FIG. 11).

FIG. 12 is a cross-sectional view of semiconductor structure 1200 after depositing and patterning dielectric material 172 and depositing resistive metal 161 in accordance with an embodiment of the present invention. As depicted, FIG. 12 includes the elements of FIG. 11 with dielectric material 172 and resistive metal 161. Also, illustrated in FIG. 12 is a distance X between dielectric material 132 and dielectric material 172. Increasing distance X can slightly increase the electrical resistance of the completed three-dimensional resistor of semiconductor structure 1300.

Like dielectric material 132 and dielectric material 142, dielectric material 172 can be any suitable dielectric material which can the same dielectric material as one of more of the previously depicted and discussed dielectric materials. For example, dielectric material 132 and dielectric material 142 may be different dielectric materials and may be different from dielectric material 12. Similarly, resistive metal 161 can be the same resistive metal as resistive metal 141 or resistive metal 161 can be a different resistive metal.

FIG. 13 is a cross-sectional view of semiconductor structure 1300 after depositing and planarizing dielectric material 192, depositing resistive metal 181, and forming top electrode 190 in accordance with an embodiment of the present invention. As depicted, FIG. 13 includes the elements of FIG. 12 and resistive metal 181, dielectric material 192, and top electrode 190.

Dielectric material 192 can be any suitable dielectric material that is deposited using known processes (e.g., CVD, PVD). Resistive metal 181 can be any of the previously discussed resistive metals or resistive metal-oxides or resistive metal nitrides (e.g., deposited by ALD on dielectric materials 182 and 172 with a 1 to 5 nm thickness). Top electrode 190 may be formed using known subtractive or damascene processes. Similar to top electrode 90 and bottom electrode 10, in some embodiments, top electrode 190 is a line or a contact in any metal level (e.g., in a BEOL metal level, a MOL metal level, or FEOL metal).

Semiconductor structure 1300 is composed of three layers of a resistive metal where each of the three resistive metals may be the same resistive metal or different resistive metals. In various embodiments, each layer of resistive metal (i.e., resistive metal 141, 161, and 181) is deposited by ALD. For example, each of the three layers of resistive metal have a thickness in the range of 1 nm to 10 nm but is not limited to this range. In semiconductor structure 1300, each adjacent layer of the three layers of resistive metal is connected by a vertical side or sidewall of the layer of resistive metal that is below it to form a three-dimensional resistor. For example, resistive metal 181 vertically connects to resistive metal 161 by the sidewall of resistive metal 161 which is around dielectric material 172. The three-dimensional resistor created by semiconductor structure 1300 includes resistive metal 141 vertically connecting to resistive metal 161, and resistive metal 161 vertically connecting to resistive metal 181. As depicted, resistive metal 141 resides on bottom electrode 10 and top electrode 190 resides on resistive metal 181.

The three-dimensional resistor of semiconductor structure 1300 includes both the horizontal resistive elements composed of the horizontal portions of each of resistive metal 141, 161, and 181 and the vertical resistive elements composed of the vertical portions of resistive metal 141, 161, and 181. In various embodiments, the three-dimensional resistor of semiconductor structure 1300 formed with very thin layers of resistive metal 141, 161, and 181 provides a high resistance. As previously discussed, using a deposition process, such as ALD, the layers of resistive metal 141, 161, and 181 can achieve a thickness of less than 5 nm (e.g., in the range of 1 nm). In other examples, two or more layers of resistive metal joined by vertical tube-like portions of the resistive metal can be formed.

While semiconductor structure 1300 depicts three horizontal layers of resistive metal where the three horizontal resistive metal layers are vertically connected by the sidewall of the resistive metal layer below it (e.g., the sidewall or tube of resistive metal 141 vertically connects to resistive metal 161). In other embodiments, more than three horizontal resistive metal layers are vertically connected by tubes of resistive metal created around a portion of a dielectric material, such as a small circular dielectric protrusion of dielectric material 132. The tubes are the sidewall of a lower or earlier deposited resistive metal formed around a patterned and etched dielectric material. In various embodiments, the horizontal portions of resistive metal 141, the horizontal portions of resistive metal 161, and the horizontal portions of resistive metal 181 form the horizontal resistive metal elements of the three-dimensional resistor and the sidewalls of resistive metal 141 and resistive metal 161 create the vertical resistive metal elements connecting the horizontal resistive metal elements of the three-dimensional resistor.

As previously discussed, in some embodiments, the width or diameter of each tube of resistive metal such as resistive metal 141 and/or resistive metal 161 is larger than the width of the line of resistive metal it resides on. In these embodiments, only two small crescent-like portions of the tube contact the resistive metal line above it, creating a higher electrical resistance in the vertical tube of resistive metal. In one embodiment, the tube of resistive metal 141 is not centered under the line of resistive metal 161. In this case, only a small vertical portion of the tube of resistive metal 141 contacts the line of resistive metal 161 creating a higher electrical resistance of the resulting three-dimensional resistor.

The three-dimensional resistor of semiconductor structure 1300 can provide even a slightly higher electrical resistance than semiconductor structure 700 due to the thin, single horizontal layer of the resistive metal (e.g., 1 nm to 5 nm thick) and the thin, vertical sidewall of the resistive metal (e.g., also, less than 5 nm thick) connecting the horizontal layers of the resistive metal. A conventional resistor providing the same amount of electrical resistance as the three-dimensional resistor of semiconductor structure 1300 would require a larger footprint or surface area in the semiconductor chip. The three-dimensional resistor of semiconductor structure 1300 reduces the resistor footprint or alternatively, can provide more electrical resistance than a conventional two-dimensional resistor with the same footprint. In this way, the three-dimensional resistors disclosed in the embodiments of the present invention can reduce wiring congestion by providing more semiconductor real estate or wiring space and/or provide improved electrical resistance compared to conventional two-dimensional resistors.

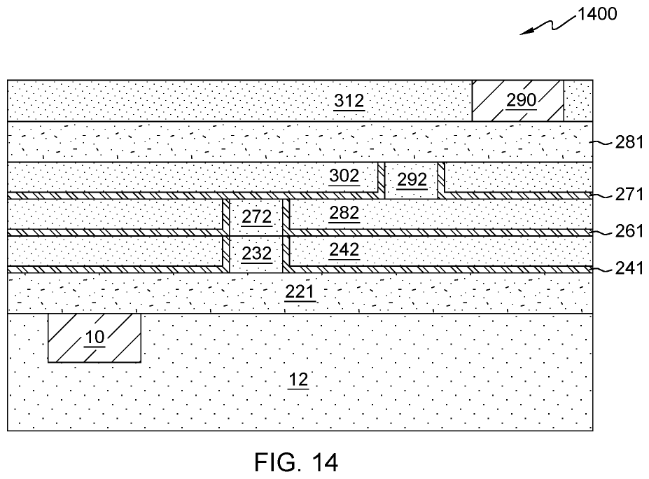

FIG. 14 is a cross-sectional view of semiconductor structure 1400 with two stacked three-dimensional resistors formed with dielectric material 241, 261, and 271 in accordance with an embodiment of the present invention. As depicted, FIG. 1400 includes bottom electrode 10 in dielectric material 12, a layer of resistive metal 221, a layer of resistive metal 241 on resistive metal 221, a vertical tube of resistive metal 221 in dielectric material 242 connecting to resistive metal 261 in dielectric material 282, resistive metal 191 in dielectric material 302, and resistive metal 281 under top electrode 290.

Semiconductor structure 1400 is another example of a three-dimensional resistor formed using the processes discussed with respect to FIGS. 1-13. Using the previously discussed processes, each of resistive metal 241, 261, 271, and 281 can be patterned into lines, rectangular islands or pads. The vertical elements or tube of resistive metal 241, 261, and 281 are formed around a remaining portion of dielectric material 232, 272, and 292, respectively. In various embodiments, resistive metal 241, 262, and 271 are deposited as a thin layer of resistive metal using ALD. In FIG. 14, resistive metal 221 under resistive metal 241 and resistive metal 281 are deposited in a thicker layer by one of CVD, PVD, or ALD, for example. In other examples, resistive metal 241 and 281 are thin layers (e.g., 1 to 5 nm thick) of resistive metal deposited by ALD. In various embodiments, resistive metal 221 is not present (depicted in FIG. 12). In these embodiments, dielectric material 232 is deposited and patterned on dielectric material 12 followed by the deposition, for example, by ALD, of resistive metal 241 on bottom electrode 10, dielectric material 232, and dielectric material 12. Resistive metal 241 is patterned and etched to form a line. A layer of dielectric material 142 is deposited and planarized (e.g., by CMP).

In semiconductor structure 1400, the tube of resistive metal 261 created by the sidewall of resistive metal 261 is directly over and connected to the tube of resistive metal 241 directly under the tube of resistive metal 261. In this example, the vertical elements of an upper layer of the resistive metal such as resistive metal 261 can be stacked directly on a vertical element or tube of a directly adjacent resistive metal layer such as resistive metal 241 in FIG. 14. As depicted in FIG. 14, when a tube of resistive metal 241 has the same width and is stacked directly over and contacting another tube of resistive metal 161, then the horizontal portion of the resistive metal 261 above dielectric material 242 can be removed (e.g., using anisotropic etch-back process). As depicted in FIG. 14, the vertical elements or tubes of resistive metal 241 and 261 have the same diameter and are vertically aligned and stacked directly on each other (e.g., the tube of resistive metal 241 is under the tube of resistive metal 261).

In some cases, directly stacking the tube or vertical element of one layer on the resistive metal tube or vertical element of the layer of resistive metal directly below it can provide a three-dimensional resistor providing both a very small footprint and good electrical resistance.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure comprising:
a three-dimensional resistor with at least two horizontal resistive metal elements connected by at least one vertical resistive metal element, wherein the at least one vertical resistive metal element surrounds a portion of a first dielectric material.

2. The semiconductor structure of claim 1, further comprises:
a bottom electrode connects to a bottom element of the at least two horizontal resistive metal elements; and
a top electrode connects to a top element of the at least two horizontal resistive metal elements.

3. The semiconductor structure of claim 1, wherein the at least one vertical resistive metal element contacting the at least two horizontal resistive metal elements is a tube around the first dielectric material.

4. The semiconductor structure of claim 1, wherein the at least two horizontal resistive metal elements are each composed of two layers of a resistive metal material.

5. The semiconductor structure of claim 1, wherein the at least one vertical resistive metal element has a sidewall thickness that is less than 5 nm.

6. The semiconductor structure of claim 1, wherein the at least one vertical resistive metal element is composed of one resistive metal.

7. The semiconductor structure of claim 1, wherein the at least one vertical resistor element and the at least two horizontal resistor elements are composed of different resistive metals.

8. The semiconductor structure of claim 3, wherein the tube of the at least one resistive metal element has a shape selected from the group consisting of a circle, an oval, a rectangle, and a square with one or more fins.

9. The semiconductor structure of claim 1, wherein the portion of the first dielectric material is between two of the at least two horizontal resistive metal layers, and wherein each layer of the at least two horizontal resistive metal layers is a single layer of resistive metal material.

10. The semiconductor structure of claim 1, wherein:
at least one horizontal resistive metal element of the at least two horizontal resistive metal elements comprises a first line of a first resistive metal, wherein the first line of the first resistive metal resides on a portion of a first metal level and a bottom dielectric material, and wherein a portion of the first line of the first resistive metal includes a vertical tube connecting to a second line of a second resistive metal;
at least a second horizontal resistive metal element of the at least two horizontal resistive metal elements comprises the second line of the second resistive metal, wherein the second line of the second resistive metal resides on a second dielectric material layer, surrounds a portion of the first dielectric material, and contacts a third line of a third resistive metal, and wherein a portion of the second line of the second resistive metal includes the vertical tube connecting to the third line of the third resistive metal; and
at least a third horizontal resistive metal element of the at least two horizontal resistive metal elements comprises the third line of the third resistive metal, wherein the third line of the third resistive metal resides a third dielectric material that resides on the second resistive metal, on a portion of a fourth dielectric material, and contacts a fourth line of a fourth resistive metal, and wherein the third line of the third resistive metal includes the vertical tube connecting to the fourth line of the fourth resistive metal.

11. A semiconductor structure comprising:
a three-dimensional resistor includes two adjacent horizontal resistive metal elements composed of a single layer of a resistive metal connected by a vertical resistive metal element, wherein the vertical resistive metal element surrounds a first dielectric material.

12. The semiconductor structure of claim 11, wherein the first dielectric material is directly contacting one horizontal surface of a first of the two adjacent horizontal resistive metal elements and the vertical resistive metal element, and wherein the vertical resistive metal element is a sidewall of a second of the two adjacent horizontal resistive metal elements.

13. The semiconductor structure of claim 12, wherein the first dielectric material has a shape selected from the group consisting of a circle, an oval, a rectangle, and a square with one or more fins.

14. The semiconductor structure of claim 11, wherein the two horizontal resistive metal elements and the vertical resistive metal element have a thickness of one to five nanometers.

15. The semiconductor structure of claim 11, wherein the two horizontal resistive metal elements and the vertical resistive metal element are composed of different resistive metal materials.

16. The semiconductor structure of claim 11, wherein the two horizontal resistive metal elements and the vertical resistive metal element are composed of a same resistive metal materials.

17. The semiconductor structure of claim 11, wherein the two horizontal resistive metal elements are each a line, and wherein a portion of one line of the two horizontal resistive metal elements has a sidewall contacting a second line of the two horizontal resistive metal.

18. The semiconductor structure of claim 11, further comprising:
a portion of a first metal layer contacting a first two horizontal resistive metal element of the two horizontal resistive metal elements; and
a portion of a second metal layer contacting a second horizontal resistive metal element of the two horizontal resistive metal elements.

19. The semiconductor structure of claim 18, wherein the portion of a first metal layer is a portion of a first metal line, and wherein the portion of a second metal layer is a portion of a second metal line.

20. A three-dimensional resistor comprising:
more than two horizontal resistive metal elements, wherein one of two adjacent horizontal resistive metal elements includes a vertical tube of the resistive metal surrounding a portion of a dielectric material connecting the two adjacent horizontal resistive metal elements; and
at least two vertical tubes of the resistive metal surrounding the portion of the dielectric material are vertically aligned and stacked, wherein the at least two vertical tubes of the resistive metal that are vertically aligned and stacked connect the more than two adjacent horizontal resistive metal elements.
